(19) United States
(12) Patent Application Publication
(10) Pub. No.: US 2024/0069101 A1
(43) Pub. Date: Feb. 29, 2024

(54) System and Method for Application-Dependent Selection of Batteries with Differentiable Programming

(71) Applicant: CARNEGIE MELLON UNIVERSITY, Pittsburgh, PA (US)

(72) Inventor: Venkatasubramanian Viswanathan, Pittsburgh, PA (US)

(21) Appl. No.: 18/011,401

(22) PCT Filed: May 14, 2022
(86) PCT No.: PCT/US22/29332

§ 371 Date: Dec. 19, 2022

Related U.S. Application Data
(60) Provisional application No. 63/188,535, filed on May 14, 2021.

(51) Int. Cl. G01R 31/36; G01R 31/367

(52) U.S. Cl. CPC G01R 31/3647; G01R 31/367

(57) ABSTRACT

Disclosed herein is a system and method for selecting a battery for a particular application, for example, batteries used in portable electronics, electric vehicles, satellites, etc. The method uses an end-to-end differentiable modeling approach that allows the selection of batteries directly from the parameters of the battery and a specification of the particular application for which the batteries are being selected.

### RELATED APPLICATIONS

This application claims the benefit of U.S. Provisional Patent Application No. 63/188,535 filed May 14, 2021, the contents of which are incorporated herein in their entirety.

### BACKGROUND OF THE INVENTION

Lithium-ion (Li-ion) batteries are widely used in a variety of industries such as portable electronics, electric vehicles and electric aircraft. Li-ion batteries face trade-offs in performance related to energy, power, life during operation (cycle life), life under no operation (shelf life), etc. The appropriate selection of Li-ion batteries for a particular application is a challenging, resource-intensive and time-consuming task.

The performance metrics of Li-ion batteries directly determine the performance capabilities of various applications including, for example, electric automobiles, trucks and aircraft. Specifically, the performance of the selected batteries in terms of specific energy, specific power and cycle life directly determine the product performance and life cycle. Thus, selection of batteries based on these performance metrics is one of the single most important tasks for electric mobility and portable electronics applications.

Heretofore, the selection of batteries has been largely heuristic based on a cursory examination of specification sheets or prolonged battery testing for a small number of test cases of the application. It would therefore be desirable to provide an improved approach for selection of the batteries based on a the performance metrics for an application-dependent scenario.

### SUMMARY OF THE INVENTION

The invention described herein relates generally to the field of lithium-ion batteries, which are widely used in a variety of industries, including, for example, as the main power source for portable electronics, electric cars, aircraft, submarines and spacecraft. Different applications require different batteries with different characteristics. For example, aircraft may require the batteries to deliver a high normalized current during the take-off and landing phases of the flight, while satellites, for example, may require a much lower normalized current during all phases of operation.

Disclosed herein is a system and method for selecting batteries for a particular application which is based on using a continuous latent space representation of the battery performance paired with a modeling block that allows direct mapping of the performance metrics for an application-dependent scenario.

The invention is based on an end-to-end differentiable modeling approach that allows the selection of batteries directly from the parameters of the cell and specifications of the cell. The specifications of the cell are encoded in a latent space (e.g., using an autoencoder), and a differentiable performance model is then built that directly maps the utility of the battery to a particular application.

### BRIEF DESCRIPTION OF THE DRAWINGS

FIG. 1 is an illustration of the derivation of a battery latent space from a battery specification.

FIG. 2 is an illustration of the derivation of an application latent space from an application specification.

FIG. 3 is an illustration of the use of a differentiable performance model to determine the suitability of a particular battery for a particular application, based on a comparison of the respective latent spaces.

### DETAILED DESCRIPTION

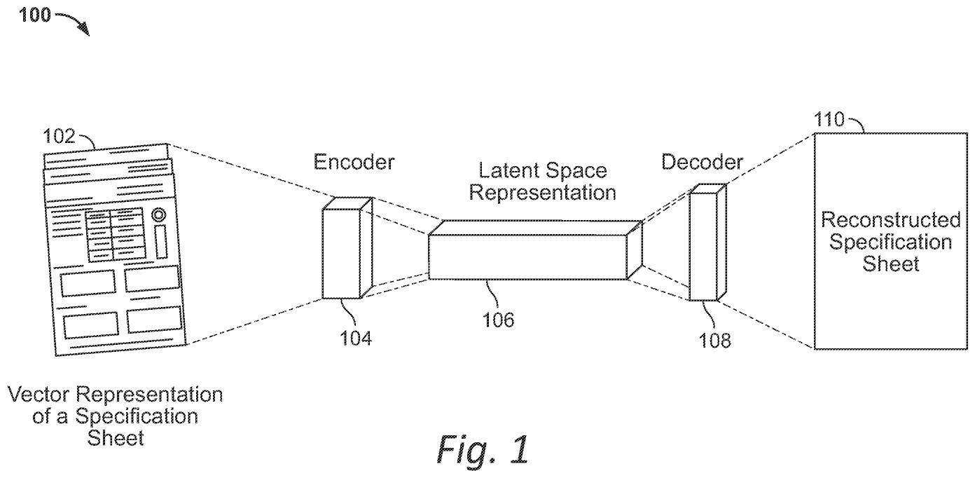

FIG. 1 illustrates network 100 for deriving a battery latent space representation for one or more batteries. For lithium-ion batteries, the input is battery specification data 102 for a particular battery and other information related to, for example, vendors, electrode material, electrolyte material etc. Feature extraction of the electrode and electrolyte is done using chemistry featurization techniques and may be implemented, in some embodiments, in RDKit, Magpie, etc. Battery specification data 102 may be a vector representation of a specification sheet specifying features and characteristics of a battery. This leads to a continuous and automatically-differentiable representation of the battery performance as a function of the input specifications.

Encoder 104 extracts features from one or more sets of data from battery specifications 102 and derives a battery latent space representation 106 of the one or more batteries. Network 100 may be an autoencoding network trained to extract the most pertinent features from battery specification 102. Battery latent space 106 may be decoded by decoder 108 to provide a reconstruction of battery specification 102 to train the autoencoding network 100 to extract only the most pertinent features from battery specification 102.

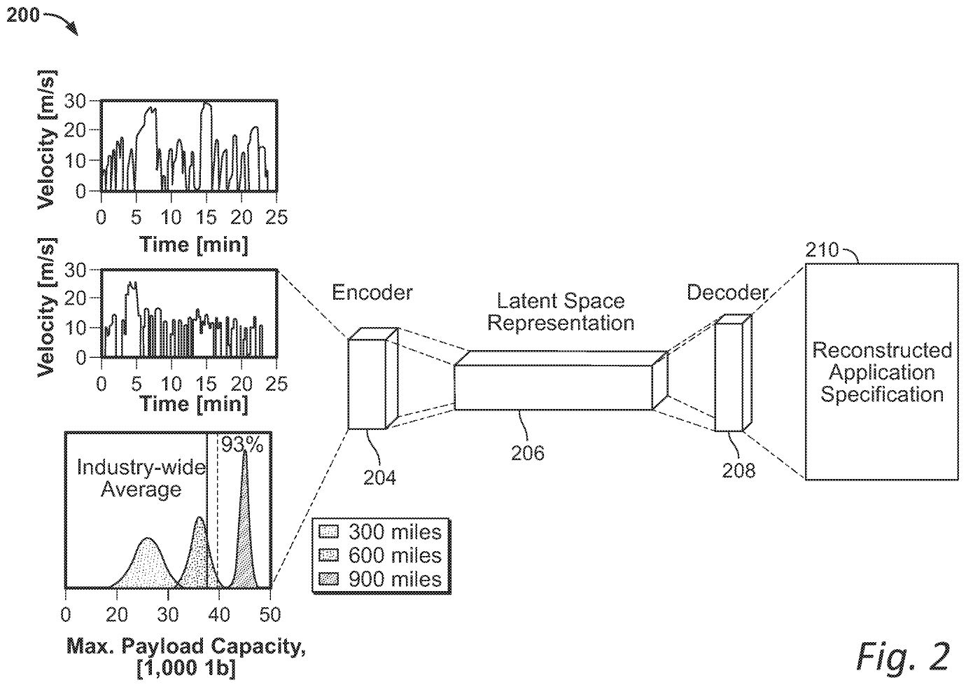

In a similar manner, a latent space representation for the application with which the battery will be used may be derived using network 200, shown in FIG. 2. The application could range from portable electronics to electric vehicles, for example, electric cars, electric aircraft, satellites, submarines, etc. FIG. 2 illustrates the process for deriving the application latent space. Application specification 202 may comprise, for example, use-profiles, drive profiles, life and performance requirements, flight mission profiles and other requirement characteristics such as payload, usable range, charge profile, discharge profile, etc. Application specification 202 may, in some embodiments, be a vector representation of the requirements and characteristics of the application.

Encoder 204 extracts features from application specification data 202 and derives an application latent space representation 206 of the application. Network 200 may be, for example, an autoencoding network trained to extract the most pertinent features from application specification 202. Application latent space 206 may be decoded by decoder 208 to provide a reconstruction of application specification sheet 210 to train the autoencoding network 200 to extract only the most pertinent features from the application specification 202.

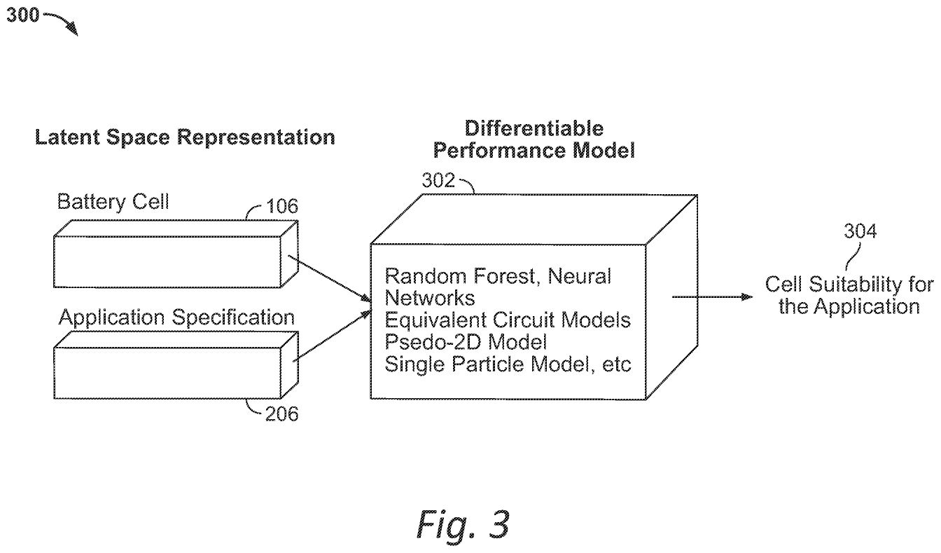

Once the battery latent space 106 and application latent space 206 have been derived, they may be evaluated to determine the suitability of a particular battery for the particular application. FIG. 3 illustrates a network 300 for determining the suitability of a battery for the particular application. In some instances, latent spaces 106 from a variety of different batteries may be evaluated with respect to the application latent space 206 to determine which battery is best suited to the particular application.

Using the the latent space representation of the one or more batteries 106 and the latent space representation for the application 206, a differentiable performance model 302 is used to directly determine the suitability of each battery for that application. The differentiable performance model 302 may, in some embodiments, be a physics-based model that is automatically differentiable, such as pseudo-2D models written in an automatically-differentiable form (e.g., Julia language) or, in other embodiments, may be a data-driven model such as a random forest or a neural network. In yet other embodiments, differentiable performance model 302 may be a fusion of a physics-based model and a data-driven model, resulting in a physics-constrained data-driven model (e.g., a physics-informed neural network, universal ordinary and partial differential equations, etc.). The differentiable performance model 302 may be trained using back-propagation.

Differentiable performance model 302 may output a value or score 304 indicating the suitability of a particular battery for the particular application. In some embodiments, the battery having the highest suitability score 304 may be selected for use with the application. In some instances, the battery may be a commercially available, off-the-shelf battery while, in other instances, the battery may be manufactured to meet the chosen battery specification 102.

Using the method of the present invention, the end-to-end differentiability from the battery specification 102 and the application specification 202 to the model 302 enables efficient navigation of the original selection space and directly provides battery selection, as well as any required changes to the battery parameters (e.g., thickness, electrode material, electrolyte material) to conform to the application requirements. From a practical perspective, the disclosed method provides an efficient way to select among different battery suppliers, different generation of batteries, etc.

As would be realized by one of skill in the art, the disclosed systems and methods described herein can be implemented by a system comprising a processor and memory, storing software that, when executed by the processor, performs the functions comprising the method. For example, the training, testing and deployment of the model can be implemented by software executing on a processor.

As would further be realized by one of skill in the art, many variations on implementations discussed herein which fall within the scope of the invention are possible. Specifically, many variations of the architecture of the model could be used to obtain similar results. The invention is not meant to be limited to the particular exemplary model disclosed herein. Moreover, it is to be understood that the features of the various embodiments described herein were not mutually exclusive and can exist in various combinations and permutations, even if such combinations or permutations were not made express herein, without departing from the spirit and scope of the invention. Accordingly, the method and apparatus disclosed herein are not to be taken as limitations on the invention but as an illustration thereof. The scope of the invention is defined by the claims which follow.

1. A method of specifying a battery for an application comprising:
deriving one or more battery latent spaces describing characteristics of one or more batteries;
deriving an application latent space describing requirements of the application; and
choosing a best fit between the one or more batteries and the application based on a comparison of the battery latent spaces and the application latent space.

2. The method of claim 1, wherein the one or more battery latent spaces are derived from a vector representations of one or more battery specifications.

3. The method of claim 2 wherein the battery latent spaces are derived using an auto encoding network trained to create the battery latent spaces of the one or more batteries.

4. The method of claim 3 wherein the application latent space is derived from a vector representation of an application specification.

5. The method of claim 4 wherein the application latent space is derived using an auto network trained to create the application latent space.

6. The method of claim 1 wherein the step of choosing the best fit between the one or more batteries and the application comprises:
submitting the one or more battery latent spaces and the latent space of the application to a differentiable performance model to determine the suitability of each battery for the application.

7. The method of claim 6 wherein the differentiable performance model outputs an indication of the suitability of the battery for the application.

8. The method of claim 7 wherein the indication is a score and furthermore wherein the battery selected for the application is a battery having the highest score.

9. The method of claim 6 wherein the differentiable performance model comprises a physics-based model.

10. The method of claim 6 wherein the differentiable performance model comprises a data-driven model.

11. The method of claim 6 when the differentiable performance model comprises a fusion of a physics-based model and a data-driven model in a differentiable programming framework.

12. The method of claim 6 wherein the differentiable performance model is a trained neural network or a set of universal and partial differential equations.

13. A system comprising:
a processor:
software, executing on the processor, the software causing the system to perform the functions of:
deriving one or more battery latent spaces describing characteristics of one or more batteries;
deriving an application latent space describing requirements of the application; and
choosing a best fit between the one or more batteries and the application based on a comparison of the one or more battery latent spaces and the application latent space.

14. The system of claim 13 wherein the one or more battery latent spaces are derived from a vector representation of one or more battery specifications and further wherein the application latent space is derived from a vector representation of an application specification.

15. The system of claim 14 wherein the one or more battery latent spaces are derived using an autoencoding network trained to create the one or more battery latent spaces and further wherein the application latent space is derived using an autoencoding network trained to create the application latent space.

16. The system of claim 12 wherein the software further causes the system to:
choose the best fit between the one or more batteries by submitting the battery latent space of each battery and the latent space of the application to a differentiable performance model to determine the suitability of each battery for the application.

17. The system of claim 16 wherein the differentiable performance model outputs an indication of the suitability of the battery for the particular application.

18. The system of claim 17 wherein the indication is a score and furthermore wherein the battery selected for the particular application is a battery having the highest score.

19. The system of claim 16 wherein the differentiable performance model comprises a physics-based model, a data-driven model or a fusion of a physics-based model and a data-driven model.

20. The system of claim 19 wherein the differentiable performance model is a trained neural network or a set of universal and partial differential equations.
